(19) United States
(12) Patent Application Publication
(10) Pub. No.: US 2006/0037937 A1
(43) Pub. Date: Feb. 23, 2006

(54) Plasma etching method

(75) Inventors: Naoki Mitsugi, Tokyo (JP); Kazumi Furuta, Tokyo (JP); Motohiro Yamada, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA HOLDINGS, INC., Tokyo (JP)

(21) Appl. No.: 11/202,824

(22) Filed: Aug. 12, 2005

(30) Foreign Application Priority Data
Aug. 23, 2004 (JP) JP2004-242707

(51) Int. Cl. B44C 1/22; C03C 25/68; H01L 21/461

(52) U.S. Cl. 216/37; 216/67; 216/59; 438/710

(57) ABSTRACT

A plasma etching method for processing a substrate material, wherein a deposition process (S09) that uses a deposition gas as a process and an etching process (S11) that uses an etching gas as a process gas are alternately and repeatedly executed, thereby etching a substrate material, and a vacuuming process (S10, S13) is interposed between the two processes so that the process gas which has just finished being used is expelled out when the process gases are switched. Thus, the etching gas and the deposition gas do not mix during each process, thereby accurately creating a high-aspect-ratio recessed and protruding pattern on the surface of a substrate material.

### BACKGROUND OF THE INVENTION

1. Field of the Invention

The present invention relates to a plasma etching method that uses plasma to process a substrate material such as silicon.

2. Description of the Related Art

Conventionally, a plasma etching method, which is a dry etching technique, has been used to etch substrates made of silicon or the like. To increase performance of semiconductor elements or to manufacture dies for large-scale integrated elements, more complicated and highly accurate substrate etching techniques have been required. Specifically, the plasma etching method has been widely applied to silicon because of silicon's excellent etching characteristics. The plasma etching is a method in which by introducing reactive gas into the vacuum (in, for example, vacuum chamber) and applying a high-frequency electric field, accelerated electrons collide with gas molecules thereby converting the gas into plasma that consists of positive ions, electrons, and neutral particles, and then a substrate material, such as a silicon substrate, is etched by using positive ions and neutral particles.

A common plasma etching method for etching a high-aspect-ratio pattern on silicon is an anisotropic etching method which forms a polymeric film on the side wall. Among these techniques, the following two methods are well known. Japanese Patent Gazette No. 2918892 (JP2918892B2) and Published Japanese Translation of PCT Application No. Hei 7-503815 (JP7-503815T) disclose conventional methods:
(1) a method in which an etching process is conducted by adding a high-deposition property gas (deposition effects) to the etching gas; and
(2) a method in which the process with high deposition properties and the process with high etching properties are alternately and repeatedly conducted in the same chamber. According to method 2, dependence of etching speed on the aspect ratio seems to be significantly reduced when compared to method 1.

The above method 2 will be further described with reference to the drawings. In method 2, processes are executed according to the process timing chart, for example, shown in FIG. 17. During the deposition process and the etching process, deposition and etching are repeatedly conducted by using an etching gas or a deposition gas, and high-frequency voltage is continuously applied to convert the gas into plasma while the gas pressure in a vacuum chamber is constant. During the etching process, bias voltage is applied slightly after an etching gas has been introduced. Furthermore, the method shown in FIG. 18 is basically the same as that of FIG. 17, but, high-frequency voltage is applied in response to the changeover between the deposition and the etching processes. Moreover, FIG. 19 shows the process timing chart of the plasma etching method disclosed in the Japanese Patent Gazette No. 2918892 (JP2918892B2), which is basically the same as the method of FIG. 17, but high-frequency voltage is applied in response to every cycle by regarding one deposition process plus one etching process as one cycle. Furthermore, each process shown in FIGS. 17 and 18 can be conducted, for example, by using an ICP (induced coupled plasma) etching system (ASE-SR made by STS). According to the description of the Japanese Patent Gazette No. 2918892 (JP2918892B2), the process shown in FIG. 19 was conducted by an ECR (electron cyclotron resonance) system.

In the above-mentioned conventional plasma etching methods, shown in FIGS. 17, 18 and 19, the deposition process and the etching process are alternately and continuously conducted to ensure continuity of the processes. When switching the processes, an intermediate condition exists in which a deposition gas mixes with an etching gas. At this intermediate point, plasma illuminates in a color different from colors that appear during the deposition process and the etching process. This intermediate condition in which an etching gas mixes with a deposition gas causes process instability, resulting in inducing an error in size of the three-dimensional pattern created on the substrate material such as silicon.

Furthermore, in the above-mentioned conventional methods shown in FIGS. 17, 18 and 19, when obtaining optimization conditions for etching and deposition processes by means of the trial-and-error method, the existence of the above-mentioned intermediate state increases the number of trials, causing the task to become complicated and an error of the etching size to occur.

### SUMMARY OF THE INVENTION

In light of the above-mentioned problems in the conventional art, an objective of the present invention is to provide a plasma etching method in which each process is stably executed by alternately and repeatedly conducting the deposition process and the etching process thereby accurately etching a substrate material.

These and other objects are attained by
a plasma etching method for processing a substrate material in a vacuum chamber, comprising
a deposition process that uses a deposition gas as a first process gas, and
an etching process that uses an etching gas as a second process gas, wherein
the deposition process and the etching process are alternately and repeatedly conducted;
said plasma etching method further comprising a vacuuming process in which one of the process gases that has just finished being used is expelled from the vacuum chamber when process gases are switched.

Furthermore, the above objective of the present invention is attained by
a plasma etching method for producing a patterned substrate comprising the steps of:
forming an etching mask pattern on the surface of a substrate material,
placing the substrate material in a vacuum chamber,
depositing a polymeric film on the substrate having the etching mask pattern thereon by introducing a deposition gas into the vacuum chamber and converting the deposition gas into a first plasma to produce a first intermediate substrate,
expelling the deposition gas from the vacuum chamber,
etching the first intermediate substrate by introducing an etching gas into the vacuum chamber and converting the etching gas into a second plasma to produce a second intermediate substrate,
repeating the depositing and the expelling the deposition gas and the etching in this order to produce the patterned substrate.

Furthermore, the above objective of the present invention is attained by
a plasma etching method for producing a patterned substrate comprising the steps of:
forming an etching mask pattern on the surface of a substrate material,
placing the substrate material in a vacuum chamber,
depositing a polymeric film on the substrate having the etching mask pattern thereon by introducing a deposition gas into the vacuum chamber and converting the deposition gas into a first plasma to produce a first intermediate substrate,
expelling the deposition gas from the vacuum chamber,
etching the first intermediate substrate by introducing an etching gas into the vacuum chamber and converting the etching gas into a second plasma to produce a second intermediate substrate,
expelling the etching gas from the vacuum chamber,
repeating the depositing, the expelling the deposition gas, the etching and the expelling the etching gas in this order to produce the patterned substrate.

According to the plasma etching method, when process gases are switched, the process gas that has just finished being used is vacuumed away before the following process gas is introduced. Accordingly, there is no such situation in which both process gases mix, and therefore, each process can be stably executed thereby making it possible to accurately etch the substrate material.

Furthermore, in the above plasma etching method, by inserting the vacuuming process between the deposition process and the etching process, when processes are switched between the deposition process and the etching process, the process gas that has just finished being used (etching gas or deposition gas) is vacuumed out of the chamber before the following process starts. Accordingly, there is no such situation in which the etching gas and the deposition gas mix, and therefore, each process can be stably executed thereby making it possible to accurately etch the substrate material.

In the above plasma etching method, it is preferable that the vacuum plasma chamber in which the substrate material is placed be vacuumed out during the vacuuming process until the inner pressure becomes equal to or below 10⁻² Pa. By reducing the pressure to or below 10⁻² Pa, it is possible to sufficiently vacuum out the process gas that has just finished being used before the following process starts, thereby being sure to avoid the situation in which the etching gas and the deposition gas mix.

Furthermore, by creating a situation where plasma generated in the deposition process and the etching process emits different colors, the normal condition of each plasma is different thereby being sure to avoid the situation in which the etching gas and the deposition gas mix.

Furthermore, during the deposition process and the etching process, each process condition can be independently controlled and executed. Because the vacuuming process is inserted between the deposition process and the etching process, each condition of the deposition process and the etching process can be independently controlled. Accordingly, by combining the conditions for the deposition process and the etching process that have been separately obtained, optimized conditions for each process can easily be obtained, thereby making it possible to accurately control the pattern of the etched substrate material.

Furthermore, the condition for the deposition process and the etching process is at least any one of gas composition, gas pressure in the vacuum chamber, high-frequency power, and high-frequency bias power, and those conditions can be properly and independently specified. For example, it is preferable that the process be controlled so that gas pressure in the etching process is low and gas pressure in the deposition process is high. Low pressure of the etching gas increases etching properties, and high pressure of the deposition gas increases deposition properties. Furthermore, it is also possible to properly set the process time for the deposition, etching, and vacuuming processes.

Furthermore, it is preferable that the etching mask disposed on the surface of the substrate material be of resist material.

Moreover, the deposition process is a film forming process which is executed to complementarily correct the etching pattern. Furthermore, it is preferable to execute the patterning of an etching mask by means of the electron beam (EB) lithography, because a three-dimensional minute structure, which is a feature of the electron beam lithography, can be accurately transferred onto the substrate material. Furthermore, an oxide film can be used as an etching mask. Moreover, it is possible to make fine adjustments of the height of the pattern created on the substrate material by controlling the selectivity of the etching mask to the substrate material.

The invention itself, together with further objects and attendant advantages, will best be understood by reference to the following detailed description taken in conjunction with the accompanying drawings.

### BRIEF DESCRIPTION OF THE DRAWINGS

FIG. 1 is a schematic diagram of an ICP etching system which is able to execute a plasma etching method according to this embodiment;

FIG. 2 is a block diagram that shows the major part of the control system of the ICP etching system shown in FIG. 1;

FIG. 3 is a cross-sectional view that schematically shows the recessed part that is being created on a silicon substrate to illustrate deposition conditions according to this embodiment;

FIG. 4 is a cross-sectional view that schematically shows the recessed part that is being created on a silicon substrate to illustrate etching conditions according to this embodiment;

FIG. 5 is a flow chart that shows steps S01 through S15 of the plasma etching method according to this embodiment;

FIGS. 6(a) and 6(b) are cross-sectional views of the silicon substrate that schematically show processes (a) and (b) in which a recessed and protruding pattern is created on the silicon substrate by the plasma etching method according to this embodiment;

FIG. 7 is a graph that shows an example of the relationships between the bias power and the selectivity in the ICP etching system shown in FIG. 1;

FIGS. 8(a), 8(b) and 8(c) are cross-sectional views of the silicon substrate that schematically show processes (a), (b), and (c) in which a step-like pattern is transferred onto the silicon substrate from the etching mask formed on the silicon substrate by the plasma etching method according to this embodiment;

FIGS. 9(a) and 9(b) are cross-sectional views of the silicon substrate that schematically show processes (a) and (b) in which a saw-edged pattern is transferred onto the silicon substrate from the etching mask formed on the silicon substrate by the plasma etching method according to this embodiment;

FIG. 10 shows the process timing in embodiments 1 through 4;

FIG. 11 shows scanning type electron micrographs of a recessed and protruding pattern (a) of the resist etching mask formed on the surface of the silicon substrate in embodiment 1 and the recessed and protruding etched pattern (b);

FIG. 12 shows scanning type electron micrographs of a recessed and protruding pattern (a) of the resist etching mask formed on the surface of the silicon substrate in embodiment 2 and the recessed and protruding etched pattern (b);

FIG. 13 is a scanning type electron micrograph of a step-like pattern created on the silicon substrate in embodiment 3;

FIG. 14 is a scanning type electron micrograph of a saw-edged pattern created on the silicon substrate in embodiment 4;

FIG. 15 is a graph that shows the spectroscopic curve of the plasma generated during the deposition process in this embodiment;

FIG. 16 is a graph that shows the spectroscopic curve of the plasma generated during the etching process in this embodiment;

FIG. 17 is a timing chart that shows the process timing for the conventional deposition and etching processes;

FIG. 18 is a timing chart that shows another process timing for the conventional deposition and etching processes; and

FIG. 19 is a timing chart that shows the process timing for the deposition and etching processes in the plasma etching method disclosed in the Japanese Patent Gazette No. 2918892.

In the following description, like parts are designated by like reference numbers throughout the several drawing.

### DESCRIPTION OF THE PREFERRED EMBODIMENT

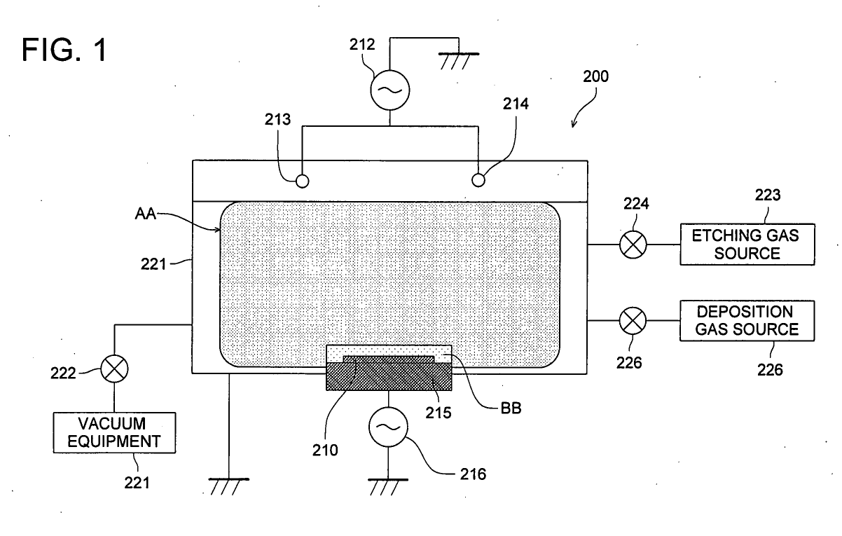

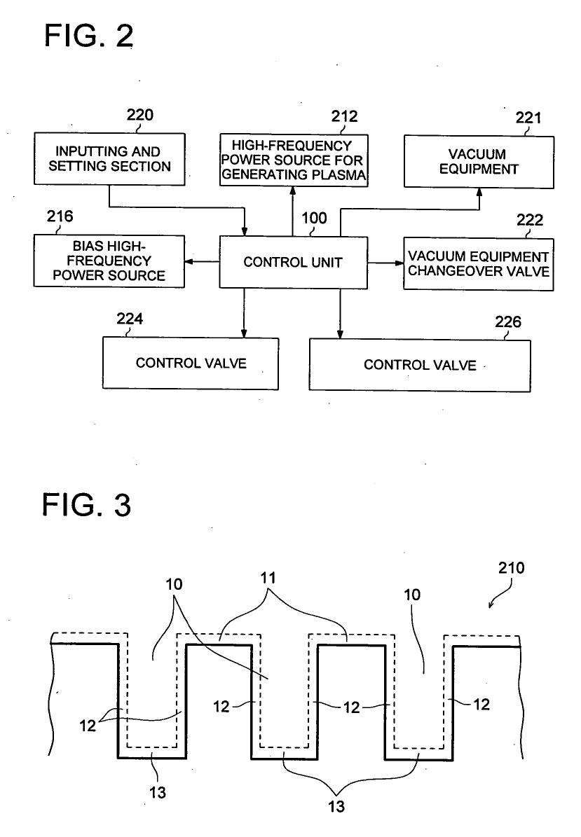

Hereafter, the preferred embodiments of the present invention will be described with reference to the drawings. FIG. 1 is a schematic diagram of an ICP (inductively-coupled plasma) etching system which is able to execute a plasma etching method according to this embodiment. FIG. 2 is a block diagram that shows the major part of the control system of the ICP etching system shown in FIG. 1.

As shown in FIG. 1, in the ICP (inductively-coupled plasma) etching system 200, a pair of high-frequency electrodes 213 and 214 connected to a high-frequency power source for generating plasma 212 is located in a vacuum plasma chamber 211, and on the opposed side that faces the high-frequency electrodes 213 and 214, a substrate holder 215 that holds a silicon substrate 210 which is a substrate material. By applying high-frequency voltage from the high-frequency power source 212 to the high-frequency electrodes 213 and 214, process gas plasma is produced in the plasma generating area AA inside the vacuum plasma chamber 211, and the silicon substrate 210 can be dry etched while supplying an etching gas into the chamber 211. Furthermore, a film can be formed on the silicon substrate 210 while supplying a deposition gas into the chamber 211.

A bias high-frequency power source 216 for controlling an etching pattern is connected to the substrate holder 215 located inside the vacuum plasma chamber 211. Bias power that is applied to the bias electrode of the substrate holder 215 causes the sheath area BB to form around the silicon substrate 210 and the substrate holder 215. By controlling the bias power by adjusting bias voltage during the etching process, it is possible to control an etching pattern of the silicon substrate 210 located in the sheath area BB.

Vacuum equipment 221 is connected to the vacuum plasma chamber 211 via a changeover valve 222. Furthermore, an etching gas source 223 is also connected to the vacuum plasma chamber 211 via a control valve 224, and a deposition gas source 225 is also connected to the vacuum plasma chamber 211 via control valve 226. Both the control valve 224 and the control valve 226 are capable of changing gas pressure within a prescribed range by controlling the gas flow rate.

As shown in FIG. 2, the ICP etching system 200 shown in FIG. 1 is equipped with a control section 100 that comprises a central processing unit (CPU). According to a prescribed sequence, the control section 100 controls the high-frequency power source for generating plasma 212, bias high-frequency power source 216 for controlling an etching pattern, vacuum equipment 221, vacuum equipment changeover valve 222, etching gas source control valve 224 and a deposition gas source control valve 226.

The control section 100, shown in FIG. 2, controls the control valves 224 and 226 so as to alternately switch the gases in the atmosphere of the vacuum plasma chamber 211 between an etching gas and a deposition gas, thereby alternately conducting the etching and deposition (film forming) of the silicon substrate 210. And when switching the process gases, the control section 100 controls the changeover valve 222 and the control valves 224 and 226 so as to vacuum out the vacuum plasma chamber 211 by the vacuum equipment 221 thereby causing inner pressure to become equal to or below 10⁻² Pa. Thus, the process gas (etching gas or deposition gas) that has just finished being used is sufficiently vacuumed away.

Furthermore, the control section 100 sets the high-frequency power (voltage) and the bias power (voltage) for generating plasma based on the preset conditions that have been inputted from the inputting and setting section 22, thereby controlling the time for the etching process, deposition process, and vacuuming process as well as controlling the flow rate of the etching gas and the deposition gas.

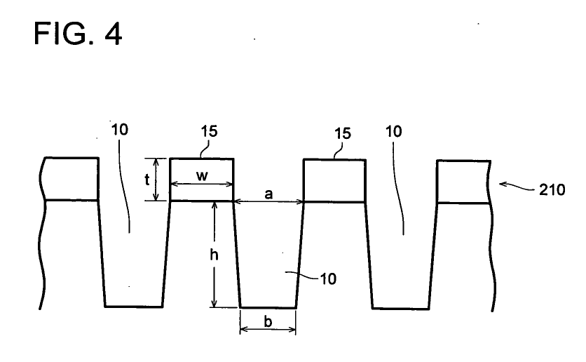

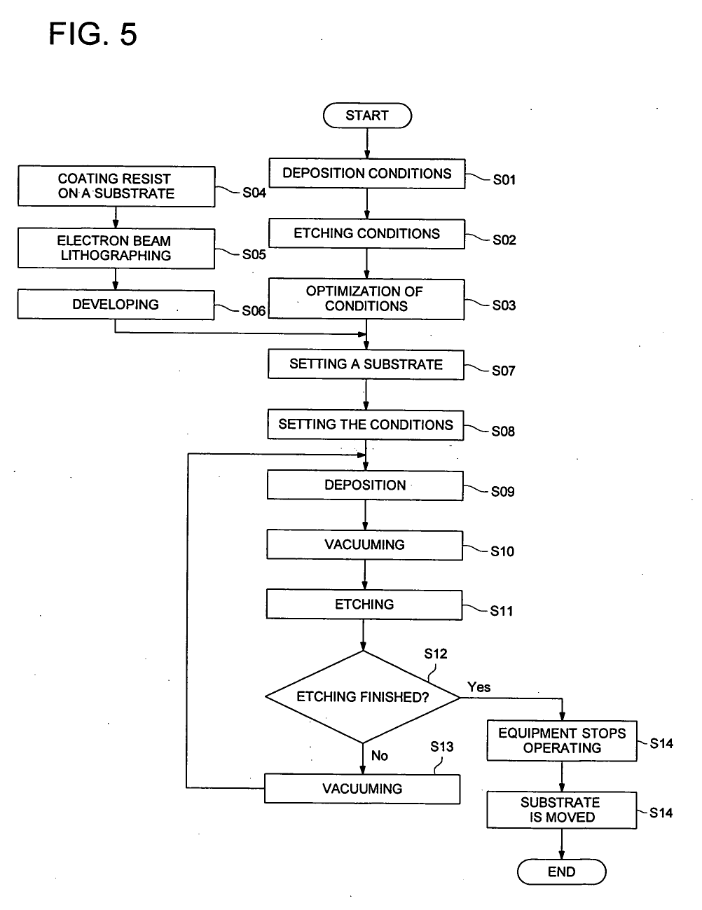

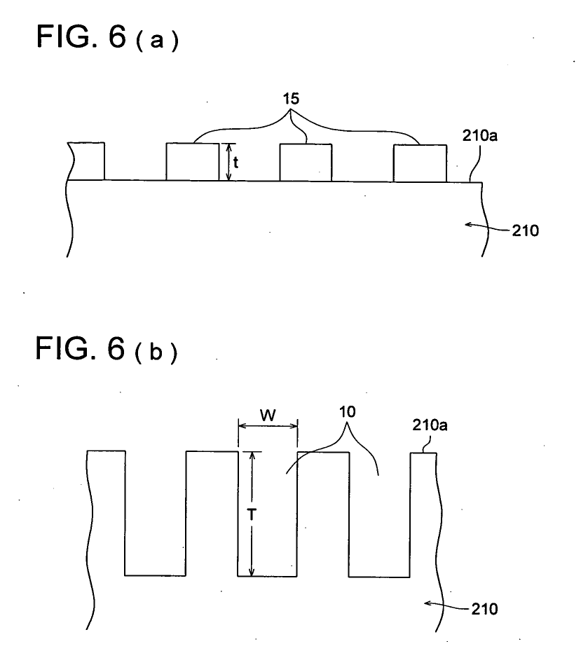

Next, a plasma etching method according to this embodiment that uses an ICP etching system shown in FIGS. 1 and 2 will be described with reference to FIGS. 3, 4, 5, 6(a) and 6(b). FIG. 3 is a cross-sectional view that schematically shows a recessed part that is being created on a silicon substrate to illustrate deposition conditions according to this embodiment. FIG. 4 is also a cross-sectional view that schematically shows a recessed part that is being created on a silicon substrate to illustrate etching conditions according to this embodiment. FIG. 5 is a flow chart that shows steps S01 through S15 conducted by a plasma etching method according to this embodiment. FIGS. 6(a) and 6(b) are cross-sectional views of the silicon substrate that schematically show processes (a) and (b) in which a recessed and protruding pattern is created on a silicon substrate by the plasma etching method shown in the flow chart of FIG. 5.

As shown in FIG. 6(a), in a plasma etching method shown in the flow chart of FIG. 5, a silicon substrate 210 having an etching mask 15 on which a prescribed minute pattern has been created by means of the electron beam lithography and development is etched with plasma, thereby etching a high-aspect-ratio recessed and protruding pattern having a recessed portion 10 of the depth T and width W as shown in FIG. 6(b).

First, deposition conditions of the silicon substrate to be etched are analyzed (S01). For example, as shown in FIG. 3, the amount of film formed (film thickness), pattern created on the film, and deposition conditions are analyzed for the surface film 11 formed on the surface of the silicon substrate 210, side wall film 12 formed on the side wall of the recessed part 10, and the bottom surface film 13 formed on the bottom surface of the recessed part 10, thereby obtaining deposition conditions such as gas composition, gas pressure (gas pressure in the vacuum chamber), high-frequency power (voltage), and deposition time.

Next, silicon substrate etching conditions are analyzed (S02). For example, as shown in FIG. 4, analysis is conducted in regard to the relationship between the silicon substrate's 210 recessed part's 10 etching pattern (width a, depth h, and the bottom surface width b of the recessed part's 10 opening) and the etching mask's 15 thickness t and width w, and the etching conditions, and then etching conditions, such as gas composition, gas pressure (gas pressure in the vacuum chamber), high-frequency power (voltage), bias power (voltage), and etching-time, are obtained.

From a plurality of deposition conditions and a plurality of etching conditions that have been separately obtained as stated above, optimization conditions are obtained by combining the deposition conditions and etching conditions necessary for etching patterns (S03). Moreover, etching patterns can be basically presumed from the pattern obtained by the etching conditions, and the deposition process is conducted to complementarily correct an recessed and protruding etching pattern.

On the other hand, after uniform coat of resist has been applied to the silicon substrate 210 (S04), and a prescribed minute pattern is lithographed on the resist surface by means of an electron beam (SO5), the substrate is then developed by using prescribed development material (S06). Thus, as shown in FIG. 6(a), an etching mask 15 having a minute pattern is created on the surface 210a of the silicon substrate 210. Moreover, data on the etching mask's 15 thickness t and width w (FIG. 4) is used to analyze the conditions obtained in the above step S02.

Furthermore, the electron beam lithographing in step S05 can be conducted, for example, by using an electron beam lithography system and a pattern drawing method which this inventor disclosed together with other inventors in the Published Unexamined Japanese Patent Application No. 2004-107793 (corresponding U.S. Patent Gazette: U.S. 2004/0135101A) and the Published Unexamined Japanese Patent Application No. 2004-54218 (corresponding U.S. Patent Gazette: U.S. 2003/0183961A). Thus, a desired three-dimensional drawing pattern can be formed on the resist film by means of an electron beam with sub-micron order high accuracy.

Next, the silicon substrate 210 with the above-mentioned etching mask 15 formed thereon is held by the substrate holder 215 located in the vacuum plasma chamber 211 shown in FIG. 1 and placed in the ICP etching system 200 (S07). Then, optimization conditions obtained in step S03 are inputted from the inputting and setting section 220 shown in FIG. 2 and set for) the ICP etching system 200 in FIG. 1 (S08).

Next, the ICP etching system 200 is operated under the above conditions; the vacuum plasma chamber 211 is vacuumed out; a deposition gas is introduced from a deposition gas source 225 to the vacuum plasma chamber 211 by means of the control valve 226; and high-frequency voltage is applied to the electrodes 213 and 214 to generate plasma, thereby conducting the deposition on the silicon substrate 210 (S09).

After that, the control valve 226 stops supplying a deposition gas, and the vacuum equipment 221 vacuums out the deposition gas until the inner pressure of the vacuum plasma chamber 211 becomes equal to or below 10⁻² Pa (S10).

Next, an etching gas is directed from an etching gas source 223 to the vacuum plasma chamber 211 by means of the control valve 224, and high-frequency voltage is applied to the electrodes 213 and 214 to generate plasma, and bias voltage is simultaneously applied to the silicon substrate 210, thereby etching the silicon substrate 210 (S11).

When the etching operation continues (S12), the control valve 224 stops supplying an etching gas, and the vacuum equipment 221 vacuums out the etching gas until the inner pressure of the vacuum plasma chamber 211 becomes equal to or below 10⁻Pa (S13).

Next, the procedure returns to the above-mentioned step S09 to conduct deposition, and subsequently, the vacuuming process (S10), and the etching process (S11) are conducted in the same manner. Thus, the deposition process and the etching process are alternately and repeatedly executed, thereby etching the silicon substrate 210.

After the above-mentioned etching process has been finished (S12), the ICP etching system 200 is stopped (S14), and the silicon substrate 210 is moved from the vacuum plasma chamber 211 (S15). By doing so, as shown in FIG. 6(b), a high-aspect-ratio (T/W) recessed and protruding pattern having a recessed part 10 of depth T and width W is created on the surface 210a of the silicon substrate 210.

As stated above, in a plasma etching method according to this embodiment, when executing deposition (S09) and etching (S11) alternately and repeatedly, the vacuuming process (S10, S13) is inserted between the two processes to sufficiently vacuum away the process gas that has just finished being used before the following process (deposition or etching) starts. Accordingly, the etching gas and the deposition gas do not mix in the following process. As a result, each process can be stably executed, and a high-aspect-ratio recessed and protruding pattern, shown in FIG. 6(b), can be accurately etched on the silicon substrate 210.

As stated above, by inserting a process for sufficiently vacuuming the vacuum plasma chamber 211 to create an inner pressure equal to or below 10⁻² Pa between the deposition process and the etching process, it is possible to completely separate the deposition process form the etching process thereby stabilizing both processes. Therefore, by individually studying etching conditions and deposition conditions and combining them, it is possible to easily control an etching pattern, thereby easily obtaining optimization conditions for both etching and deposition and increasing productivity.

Furthermore, since there is no occurrence of a deposition gas and an etching gas mixing, there are only two plasma colors: one for the deposition process and the other for the etching process. Accordingly, the deposition process and the etching process are easily distinguished according to their color, and therefore, the process can be accurately controlled.

Furthermore, it is preferable that the process be controlled so that gas pressure during the etching process is low and gas pressure during the deposition process is high. Low-pressure etching gas increases etching properties, and high-pressure deposition gas increases deposition properties.

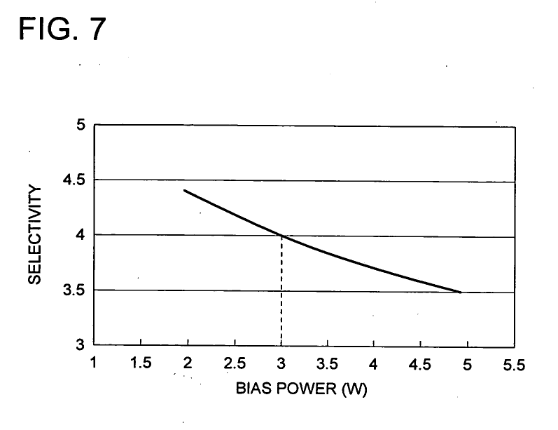

Moreover, it is possible to beforehand make settings so that the end of the etching in step S12 is determined according to the number of repeated etching processes (S11) and total etching time. Therefore, for example, it is possible to finish the etching process at the point when the etching mask 15 is completely eliminated from the surface 210a of the silicon substrate 210 by beforehand obtaining and setting the etching time. In this case, for example, assuming the selectivity to be 4, in FIGS. 6(a) and 6(b), because of T/t=4, a recessed part 10 with the depth of 4×t=T can be formed. The selectivity can be a desired value by setting the bias power of the bias high-frequency power source 216 for the ICP etching system 200 shown in FIG. 1 to the selectivity value shown in the example of FIG. 7. For example, when the selectivity is 4, the bias power is set to 3 W and applied to the silicon substrate 210. Thus, it is possible to adjust the selectivity by using only bias power applied to the silicon substrate as a parameter. The etching selectivity of the etching mask to the silicon substrate matches the selectivity of the etching condition and is uniquely determined.

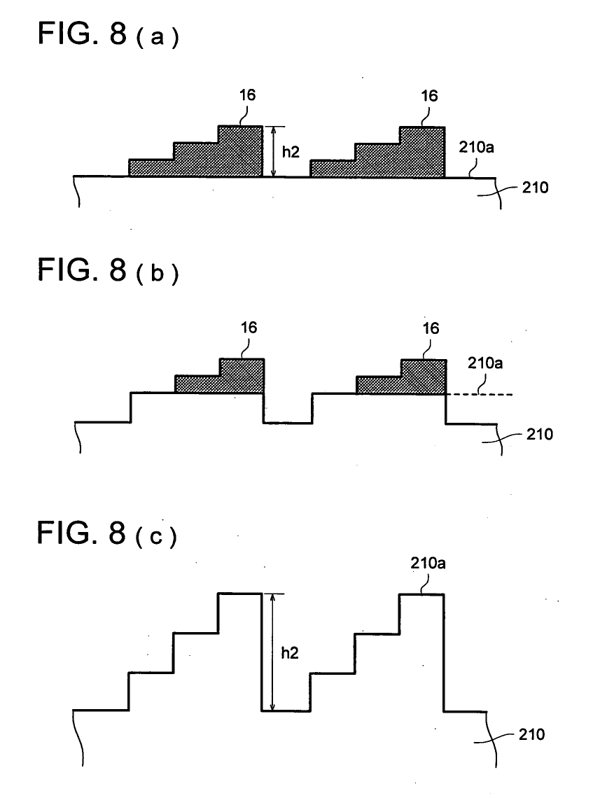

Next, an example where a silicon substrate is etched to create a step-like pattern thereon by the plasma etching method according to this embodiment will be described with reference to FIG. 8. FIGS. 8(a), 8(b) and 8(c) are cross-sectional views that schematically show the processes (a), (b), and (c) in which a step-like pattern is transferred and etched onto the silicon substrate from the etching mask formed on the silicon substrate by the plasma etching method shown in FIG. 5.

As shown in FIG. 8(a), by lithographing a pattern on the resist formed on the surface 210a of the silicon substrate 210 by means of an electron beam and developing the pattern, a step-like pattern etching mask 16 is formed as shown in the drawing. The maximum height of this etching mask 16 is h1 and the pattern corresponds to the target step-like pattern shown in FIG. 8(c).

Deposition conditions and etching conditions for the step-like pattern created on the etching mask 16 of the silicon substrate 210 shown in FIG. 8(a) and the target step-like pattern in FIG. 8(c) are analyzed in the same manner as steps S01 through S03 in FIG. 5, and optimization conditions are obtained by combining optimal deposition conditions and etching conditions necessary for the etching pattern.

According to the above-mentioned optimization conditions, the silicon substrate 210 is etched by the ICP etching system 200 shown in FIGS. 1 and 2 in the same manner as FIG. 5. As shown in FIG. 8(b), the surface 210a of the silicon substrate 210 is etched starting from a thin portion of the etching mask 16 and later, a thick portion of the etching mask 16 is used for the etching.

Thus, as shown in FIG. 8(c), the etching continues until the entire etching mask 16 vanishes, and at the time the etching mask 16 vanishes in step S11 of FIG. 5, the etching process is finished. Consequently, as shown in FIG. 8(c), the etching mask 16 completely vanishes, and the surface 210a of the silicon substrate 210 is etched to create a step-like pattern with the maximum height of h2. In this case, as well as in the same manner above, for example, assuming the selectivity to be 4, because of h2/h1=4, a step-like pattern that is expressed by 4×h1=h2 can be accurately created on the silicon substrate 210.

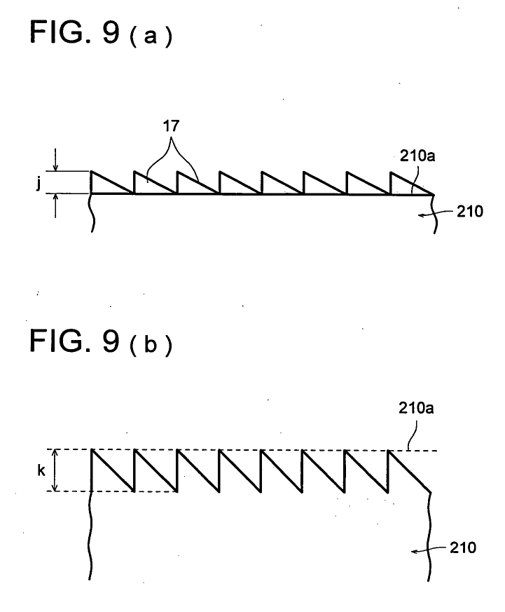

Next, an example where a silicon substrate is etched to create a saw-edged pattern by the plasma etching method according to this embodiment with reference to FIGS. 9(a) and 9(b). FIGS. 9(a) and 9(b) are cross-sectional views that schematically show processes (a) and (b) in which a saw-edged pattern is transferred and etched onto the silicon substrate from the etching mask formed on the silicon substrate by the plasma etching method according to the flow chart shown in FIG. 5.

As shown in FIG. 9(a), by lithographing a pattern on the resist formed on the surface 210a of the silicon substrate 210 by means of an electron beam and developing the pattern, a saw-edged pattern etching mask 17 is created as shown in the drawing. The maximum height of this etching mask 17 is j and the pattern corresponds to the target saw-edged pattern shown in FIG. 9(b).

Deposition conditions and etching conditions for the saw-edged pattern created on the etching mask 16 of the silicon substrate 210 shown in FIG. 9(a) and the target saw-edged pattern shown in FIG. 9(b) are analyzed in the same manner as steps S01 through S03 in FIG. 5, and optimization conditions are obtained by combining optimal deposition conditions and etching conditions necessary for the etching pattern.

According to the above-mentioned optimization conditions, the silicon substrate 210 is etched by the ICP etching system 200 shown in FIGS. 1 and 2 according to the flow chart shown in FIG. 5. The etching is executed until the etching mask 17 completely vanishes as shown in FIG. 9(b), and when the etching mask 17 vanishes in step S11 of FIG. 5, the etching process is finished. Consequently, as shown in FIG. 9(b), the etching mask 17 completely vanishes, and the surface 210a of the silicon substrate 210 is etched to create a saw-edged pattern with the maximum height of k. In this case, also in the same manner as the above, for example, assuming the selectivity to be 2, because of k/j=2, a saw-edged pattern that is expressed by 2×j=k can be accurately formed on the silicon substrate 210.

### EMBODIMENT

Next, the plasma etching method according to the present invention will be specifically described through embodiments 1 through 4.

In embodiment 1, a recessed and protruding pattern is created on a silicon substrate at the 200-nm cycle. In embodiment 2, a recessed and protruding pattern is created on a silicon substrate at the 600-nm cycle. In embodiment 3, a four-story step-like pattern is created on a silicon substrate. In embodiment 4, a saw-edged pattern is created on a silicon substrate.

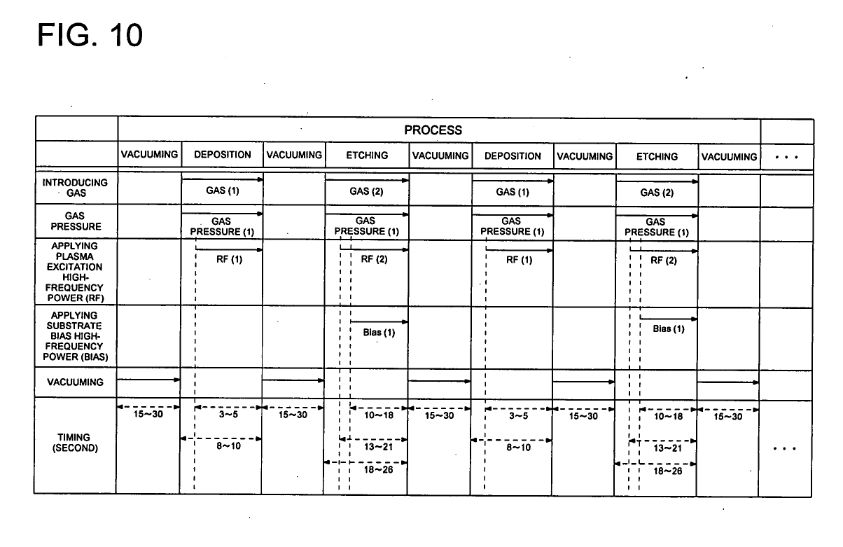

The name of the ICP etching system and process conditions used in embodiments 1 through 4 are as described below, and the deposition process and the etching process were repeatedly and alternately conducted with the vacuuming process (vacuuming) interposed between the two processes according to the timing shown in FIG. 10.

### Embodiments 1 and 2

Equipment maker: ULVAC, Inc., model: CE300I, equipment name: ICP etching system
Gas (1) (deposition gas): C₄F₈
Deposition gas pressure: 1.33 Pa
Gas (2) (etching gas): SF₆/O₂
Etching gas pressure: 0.3 Pa
Plasma excitation high-frequency output during deposition: 300 W
Plasma excitation high-frequency output during etching: 150 W
Bias output: 3 W
Vacuum pressure during vacuuming process: 0.006-0.009 Pa

### Embodiments 3 and 4

Equipment maker: ULVAC, Inc., model: CE300I, equipment name: ICP etching system
Gas (1) (deposition gas): C₄F₈
Deposition gas pressure: 1.33 Pa
Gas (2) (etching gas): SF₆/O₂
Etching gas pressure: 0.6 Pa
Plasma excitation high-frequency output during deposition: 300 W
Plasma excitation high-frequency output during etching: 120 W
Bias output: 5 W
Vacuum pressure during vacuuming process: 0.006-0.009 Pa

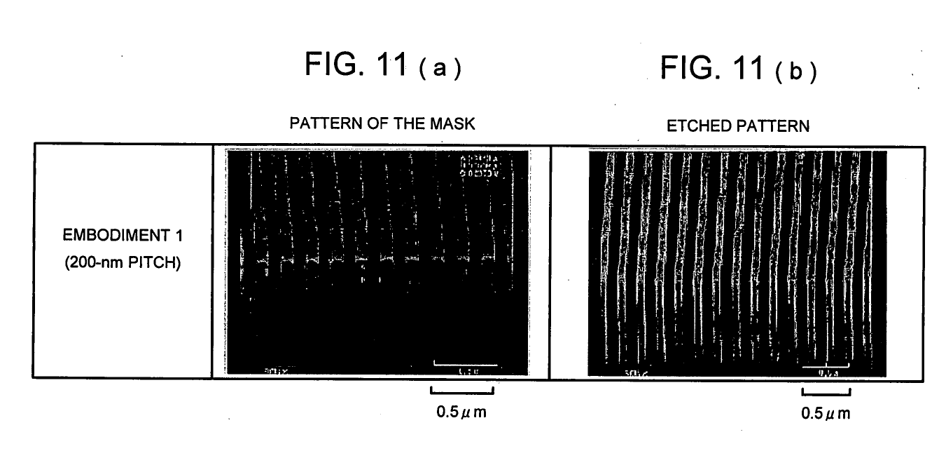

FIG. 11 shows scanning type electron micrographs of a recessed and protruding pattern (200-nm period) created on the resist etching mask formed on the surface of the silicon substrate in the embodiment 1 and the etched recessed and protruding pattern. FIG. 11(a) shows the recessed and protruding pattern created on the etching mask, and FIG. 11(b) shows an etched recessed and protruding pattern. The recessed and protruding pattern shape of the etching mask is period 200 nm, space 90 nm wide, line 110 nm wide, 280 nm high, aspect ratio of space department (height/space width) 3.1. In contrast, the recessed and protruding pattern shape formed by the surface of a silicon substrate after etching was period 200 nm, space width (ditch width) 95 nm, line 105 nm wide, 950 nm high, aspect ratio (height/space width) 10. As mentioned above, a high-aspect-ratio recessed and protruding pattern has been accurately created on the silicon substrate.

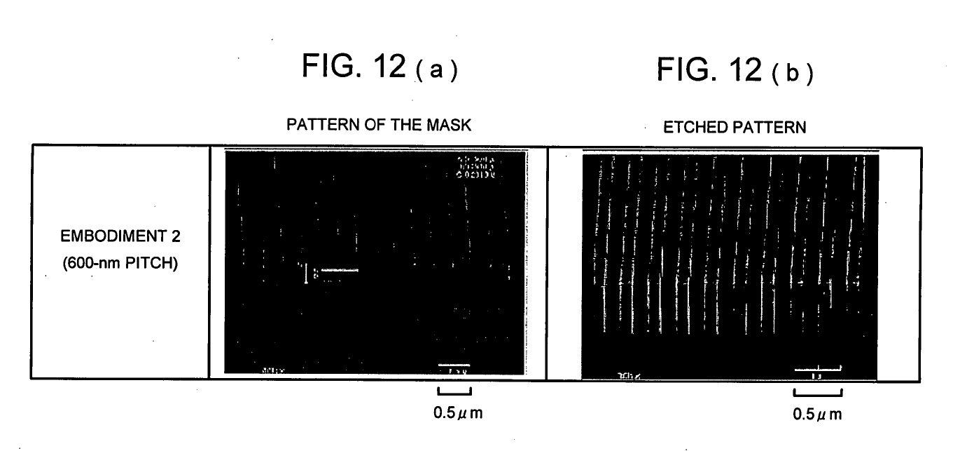

FIG. 12 shows scanning type electron micrographs of a recessed and protruding pattern (600-nm period) created on the resist etching mask formed on the surface of the silicon substrate in the embodiment 2 and the etched recessed and protruding pattern. FIG. 12(a) shows the recessed and protruding pattern created on the etching mask, and FIG. 12(b) shows an etched recessed and protruding pattern. The recessed and protruding pattern shape of the etching mask is period 600 nm, space 290 nm wide, line 310 nm wide, 300 nm high, aspect ratio 1.1 of space department. In contrast, the recessed and protruding pattern shape formed by the surface of a silicon substrate after etching was period 600 nm, space width (ditch width) 335 nm, line 265 nm wide, 1140 nm high, aspect ratio 3.4. As mentioned above, a high-aspect-ratio recessed and protruding pattern has been accurately created on the silicon substrate.

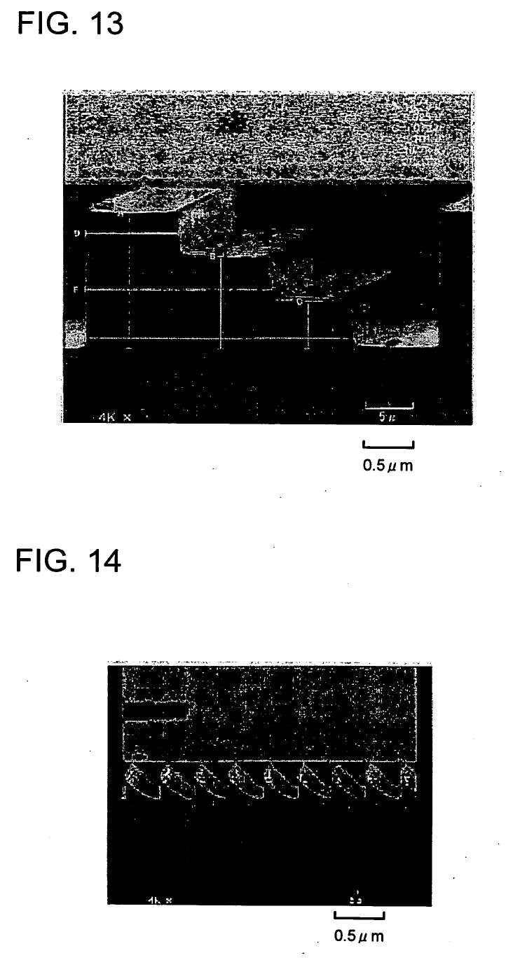

FIG. 13 is a scanning type electron micrograph of a step-like pattern created on a silicon substrate in the embodiment 3. A step-like pattern has been accurately created on the silicon substrate.

FIG. 14 is a scanning type electron micrograph of a saw-edged pattern created on a silicon substrate in the embodiment 4. A saw-edged pattern has been accurately created on the silicon substrate.

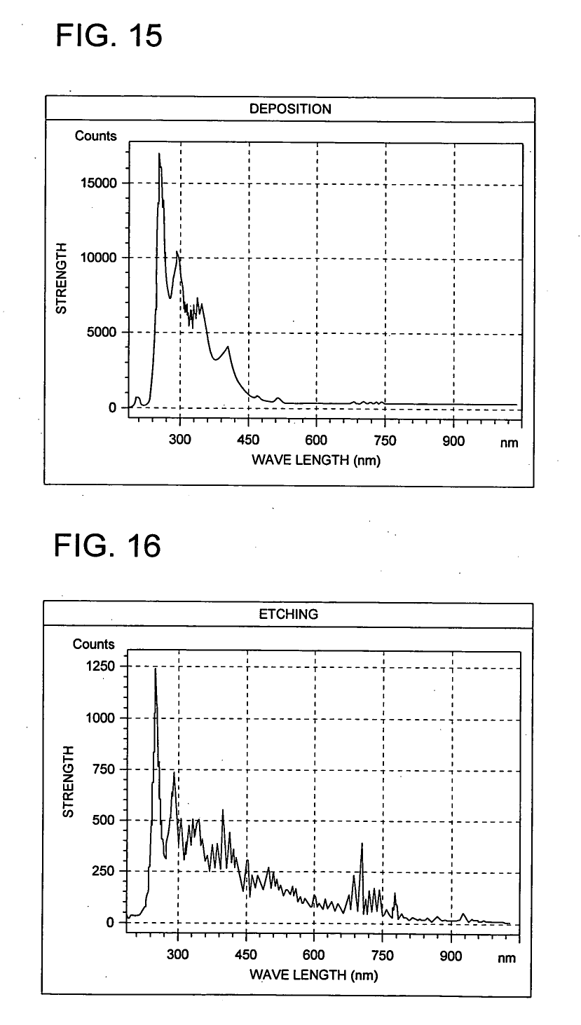

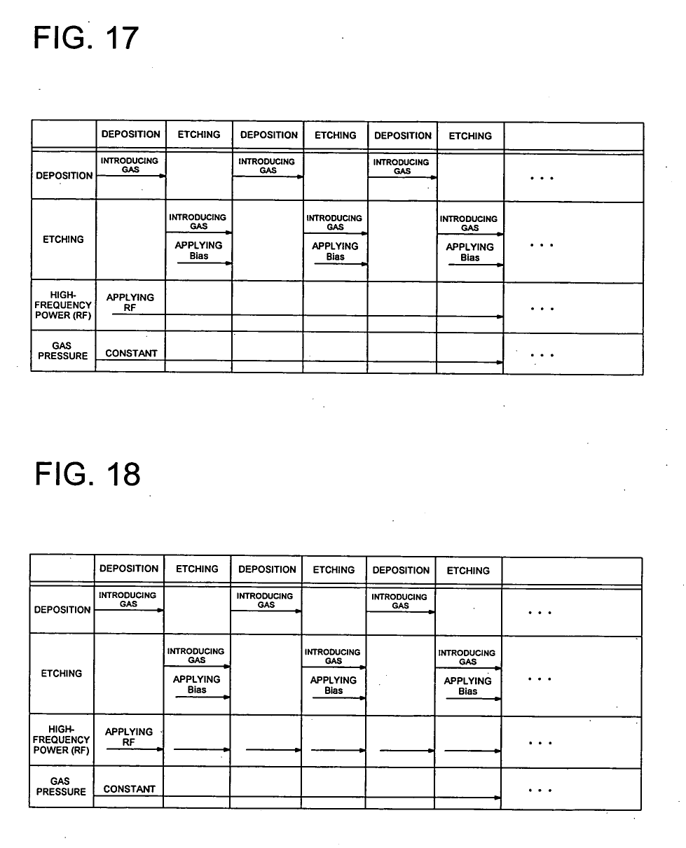

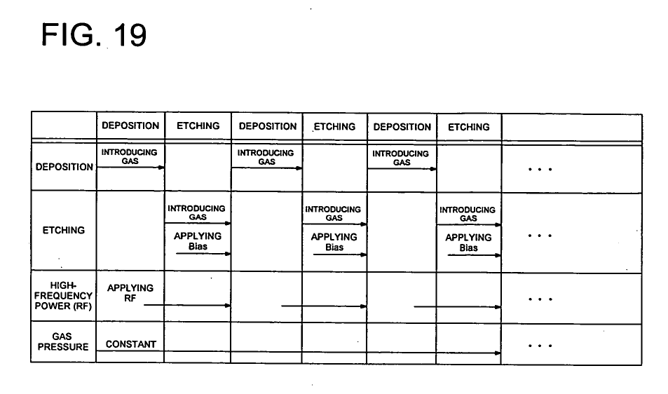

FIGS. 15 and 16 show the spectroscopic curves of the plasma generated during the deposition process and the etching process in the above embodiments. The color of the plasma generated during the deposition process is lighter than the color of the plasma generated during the etching process; thus, colors of the two plasmas are clearly distinguishable.

As stated above, preferred embodiments of the present invention have been described, however, the present invention is not intended to be limited to those embodiments, and a variety of alterations are possible within the technical concept of the present invention. For example, etched patterns created by the plasma etching method according to this embodiment include a recessed and protruding pattern, step-like pattern, and saw-edged pattern, but, other patterns are also possible. Furthermore, at least two different kinds of patterns can coexist. Moreover, the types of the etching gas and the deposition gas can be changed as required.

Furthermore, the vacuuming process described in this embodiment is conducted between the deposition process and the etching process, and it is also preferable that the vacuuming process be conducted during the following occasions as required:
(1) when types of etching gases are switched during the etching process
(2) when types of deposition gases are switched during the deposition process

In the above occasions, the vacuuming process can be conducted when process gases are switched during each process in order to avoid the situation in which different types of gases mix. By conducting a vacuum operation during each process to prepare for the exchange of gases, it is possible to prevent different types of gases from mixing and thereby accurately control each process.

According to the above-mentioned embodiment, when a substrate material is etched by the plasma etching method, it is possible to stably execute the deposition process and the etching process by alternately and repeatedly executing the deposition process and the etching process, thereby accurately etching a substrate material.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. A plasma etching method for processing a substrate material in a vacuum chamber, comprising
a deposition process that uses a deposition gas as a first process gas, and
an etching process that uses an etching gas as a second process gas, wherein
the deposition process and the etching process are alternately and repeatedly conducted;
said plasma etching method further comprising a vacuuming process in which one of the process gases that has just finished being used is expelled from the vacuum chamber when process gases are switched.

2. A plasma etching method according to claim 1, wherein said vacuuming process is executed between said deposition process and said etching process.

3. A plasma etching method according to claim 1, wherein inner pressure of the vacuum chamber in which said substrate material is placed is reduced to or below 10⁻² Pa during said vacuuming process.

4. A plasma etching method according to claim 1, wherein plasma in said deposition process and in said etching process emits different colors.

5. A plasma etching method according to claim 1, wherein the etching condition in the deposition process and the etching condition in the etching process are independently controlled.

6. A plasma etching method according to claim 5, wherein the etching condition in said deposition process and the etching condition in said etching processes at least any one of gas composition, gas pressure, high-frequency power, and high-frequency bias power.

7. A plasma etching method according to claim 1, wherein an etching mask has been disposed on the surface of said substrate material.

8. A plasma etching method according to claim 7, wherein said etching mask has a period structure having a rectangle cross-section.

9. A plasma etching method according to claim 7, wherein an etching mask that has been disposed on the surface of said substrate material is a three-dimensional pattern.

10. A plasma etching method according to claim 9, wherein said etching mask has a period structure having a saw-edged cross-section.

11. A plasma etching method according to claim 9, wherein said etching mask has a period structure having a step-like cross-section.

12. A plasma etching method according to claim 7, wherein said etching mask that has been disposed on the surface of said substrate material is made of resist material.

13. A plasma etching method according to claim 1, wherein the substrate material is a silicon substrate.

14. A plasma etching method for producing a patterned substrate comprising the steps of:
forming an etching mask pattern on the surface of a substrate material,
placing the substrate material in a vacuum chamber,
depositing a polymeric film on the substrate having the etching mask pattern thereon by introducing a deposition gas into the vacuum chamber and converting the deposition gas into a first plasma to produce a first intermediate substrate,
expelling the deposition gas from the vacuum chamber,
etching the first intermediate substrate by introducing an etching gas into the vacuum chamber and converting the etching gas into a second plasma to produce a second intermediate substrate,
repeating the depositing and the expelling the deposition gas and the etching in this order to produce the patterned substrate.

15. A plasma etching method according to claim 14, further comprising steps of expelling the etching gas from the vacuum chamber and executing the expelling the etching gas after the etching and before the depositing.

16. A plasma etching method according to claim 15, wherein the expelling the etching gas is executed repeatedly after each of the etching and before each of the depositing.

17. A plasma etching method according to claim 14, wherein the etching mask pattern is made of resist material.

18. A plasma etching method according to claim 14, wherein the substrate material is a silicon substrate.

19. A plasma etching method for producing a patterned substrate comprising the steps of:
forming an etching mask pattern on the surface of a substrate material,
placing the substrate material in a vacuum chamber,
depositing a polymeric film on the substrate having the etching mask pattern thereon by introducing a deposition gas into the vacuum chamber and converting the deposition gas into a first plasma to produce a first intermediate substrate,
expelling the deposition gas from the vacuum chamber,
etching the first intermediate substrate by introducing an etching gas into the vacuum chamber and converting the etching gas into a second plasma to produce a second intermediate substrate,
expelling the etching from the vacuum chamber,
repeating the depositing, the expelling the deposition gas, the etching and the expelling the etching gas in this order to produce the patterned substrate.

20. A plasma etching method according to claim 19, wherein the substrate material is a silicon substrate.
